(19) United States
(12) Patent Application Publication
(10) Pub. No.: US 2008/0296562 A1
(43) Pub. Date: Dec. 4, 2008

(54) Methods and apparatus for fabricating carbon nanotubes and carbon nanotube devices

(76) Inventors: James M. Murduck, Ellicott City, MD (US); John Douglas Adam, Millersville, MD (US); James E. Baumgardner, Ellicott City, MD (US); Aaron A. Pesetski, Gambrills, MD (US); Hong Zhang Pesetski, Gambrills, MD (US); John Xavier Przybysz, Severna Park, MD (US)

Correspondence Address: ANDREWS KURTH LLP;Intellectual Property Department, Suite 1100, 1350 I Street, N.W., Washington, DC, 20005, US

(21) Appl. No.: 11/806,365

(22) Filed: May 31, 2007

(51) Int. Cl. H01L 51/40; H01L 51/30; C25D 7/00

(52) U.S. Cl. 257/40; 438/99; 204/242; 219/678; 257/E51.006; 257/E51.04

(57) ABSTRACT

Methods and apparatus for fabricating carbon nanotubes (CNTs) and carbon nanotube devices. These include a method of fabricating self-aligned CNT field-effect transistors (FET), a method and apparatus of selectively etching metallic CNTs and a method and apparatus of fabricating an oxide in a carbon nanotube (CNT) device. These methods and apparatus overcome many of the disadvantages and limitations of the prior art.

### BACKGROUND

Carbon nanotubes (CNT) hold promise as a device material that is inherently small (˜1-2 nm), inherently one-dimensional with near perfect crystalline order allowing ballistic transport over relatively large distances. The utility of these features is such that CNTs allow for inherently fast device operation. Projected device operating speeds are up to a terahertz (THz). The one-dimensional nature of the CNT material allows only discrete quantized states that lead to high-linearity at much lower power than current electronic devices.

One implementation of CNTs that take advantage of these properties is a CNT field-effect transistor (FET). A typical geometry of a CNT FET includes a CNT connecting two metallic pads that serve as drain and source. A gate dielectric is deposited on top of the CNT. Additional metal is deposited above the gate dielectric to serve as the gate metal. The gate dielectric electrically isolates the CNT from the additional metal. A wiring dielectric is deposited above the gate, drain and source and the entire structure is on an insulating substrate.

Unfortunately, CNT FETs currently suffer from a number of limitations. For example, in the above configuration, the length of the CNT must be at least the width of the gate layer plus twice the distance allowed for layer-to-layer alignment error (i.e., twice the distance of the layer-to-layer (e.g., drain-to-gate and gate-to-source) spacing). These requirements can reduce device performance since (1) the CNT may not allow ballistic transport for the entire distance between the drain and source and (2) the length that the gate voltage can couple to the CNT is only a fraction of the length of the CNT, reducing the responsiveness of the CNT FET.

Moreover, current CNT fabrication methods have certain disadvantages. For example, issues arise during the growth of CNTs that prevent or limit larger-scale integration of CNTs. As a CNT begins its growth, typically from an iron particle that serves as a catalyst, the nanotube “wraps” in upon itself in a variety of modes. In other words, various nanotubes may begin wrapping at different times and in different manners. The wrapping of the nanotube is known as the nanotube's “chirality”. The chirality of each CNT dictates the electronic properties of the CNT. In practice, the variation in chirality of CNTs dictates that approximately two-thirds of the CNTs are semi-conducting and one-third are metallic. In device, such as CNT FET, fabrication, the metallic CNTs will short out the desired semi-conducting CNTs.

Additionally, in order to fabricate a device (e.g., a CNT FET) to take advantage of the above-described properties of CNTs, a thin, high-dielectric, gate oxide is often included. The gate oxide may be placed either above or below the CNTs in a typical integrated circuit implementation of such a device. However, depositing an oxide on to CNTs can be problematic. For example, the oxygen, often activated oxygen in deposition processes, may react with and damage the CNTs. Likewise, growing CNTs on the oxide material, where the oxide is placed below the CNTs, can also be problematic. For example, a reduced atmosphere is often used in the growth of CNTs (e.g., such as when chemical vapor deposition (CVD) is used to grow CNTs), and the reduced atmosphere may decompose the oxide, destroying its dielectric integrity.

### SUMMARY

An advantage of the embodiments described herein is that they overcome disadvantages of the prior art.

For example, some embodiments described herein overcome the limitations of CNT FETs. These advantages and others are achieved by a method of fabricating self-aligned carbon nanotube (CNT) field-effect transistors (FET) includes providing a substrate that is fabricated from a ultraviolet (UV) radiation transparent material, placing one or more CNTs on a front-side of the substrate, depositing a UV radiation-opaque material on a portion of the CNTs as FET drain and source, applying photoresist (PR) on a portion of the CNTs not covered by UV radiation-opaque material and on top of the UV radiation-opaque material, illuminating a bottom-side of the substrate with UV radiation, whereby the UV radiation passes through the substrate and exposes a portion of the PR to the UV radiation, developing the UV radiation-exposed PR, whereby the developed PR is removed, depositing a bi-layer, defining a FET gate, and applying a PR mask. These advantages are also achieved by a CNT FET manufactured according to the method.

Likewise, some embodiments described herein overcome the effects of chirality. These advantages and others are achieved by a method of selectively etching metallic CNTs. The method includes providing a substrate, placing a plurality of CNTs on a surface of the substrate, in which the CNTs include semi-conducting CNTs and metallic CNTs, depleting conduction electrons in the semi-conducting CNTs, whereby at least some of the semi-conducting CNTs are prevented from conducting, and burning out the metallic CNTs.

These advantages and others are also achieved by an apparatus for selectively etching metallic CNTs. The apparatus includes a substrate, a plurality of CNTs including metallic CNTs and semi-conducting CNTs, an insulating layer, a conducting layer, a voltage source, in which the voltage source bias the conducting layer so as to deplete the semi-conducting CNTs of conduction electrons, and a microwave source, in which the microwave source applies microwave radiation to the CNTs, causing the metallic CNTs to conduct current until burning out.

Additionally, some embodiments described herein overcome the oxide deposition problems. These and other advantages may be achieved by a method of fabricating an oxide in a carbon nanotube (CNT) device. Embodiments of the method include providing a substrate, depositing an anodizable metal layer on a surface of the substrate, placing one or more CNTs on the anodizable metal layer, and anodizing the anodizable metal layer beneath the one or more CNTs, whereby an oxide layer is created beneath the one or more CNTs.

These and other advantages may also be achieved by an apparatus for fabricating an oxide in a carbon nanotube (CNT) device. Embodiments of the apparatus include a substrate, an anodizable metal layer on a surface of the substrate, one or more CNTs placed on the anodizable metal layer, an anode, a electrolytic solution submerging the anode and the anodizable metal layer, and a voltage source connected to the anode and the anodizable metal layer, in which the voltage source applies a voltage to the anode and the anodizable metal layer, anodizing the anodizable metal layer to produce an oxide beneath the one or more CNTs.

### DESCRIPTION OF THE DRAWINGS

The detailed description will refer to the following drawings, wherein like numerals refer to like elements, and wherein:

FIG. 1 is a flowchart illustrating an embodiment of a method of fabricating a self-aligned carbon nanotube FET.

FIGS. 2A-2I are block diagrams illustrating exemplary steps of an embodiment of a method of fabricating a self-aligned carbon nanotube FET.

FIG. 3 is a block diagram illustrates an embodiment of a self-aligned carbon nanotube FET fabricated according to an embodiment of a method of fabricating a self-aligned carbon nanotube FET.

FIG. 4 is a flowchart illustrating an embodiment of a method of selectively etching metallic carbon nanotubes.

FIG. 5 is a block diagram illustrating an embodiment of an apparatus for selectively etching metallic carbon nanotubes

FIG. 6 is a flowchart illustrating an embodiment of a method of fabricating an oxide in a carbon nanotube device.

FIGS. 7A-7E are block diagrams illustrating exemplary steps of an embodiment of a method of fabricating an oxide in a carbon nanotube device and an apparatus for fabricating an oxide in a carbon nanotube device.

### DETAILED DESCRIPTION

Various methods and apparatus for overcoming the problems identified above are described herein. The embodiments described herein enable the fabrication of improved CNT devices, including improved CNT FETs and other integrated circuits. Certain of the various methods and apparatus described herein may be combined in order to fabricate improved CNT devices with the benefits from each.

Self-Aligned CNT FET Fabrication Processes

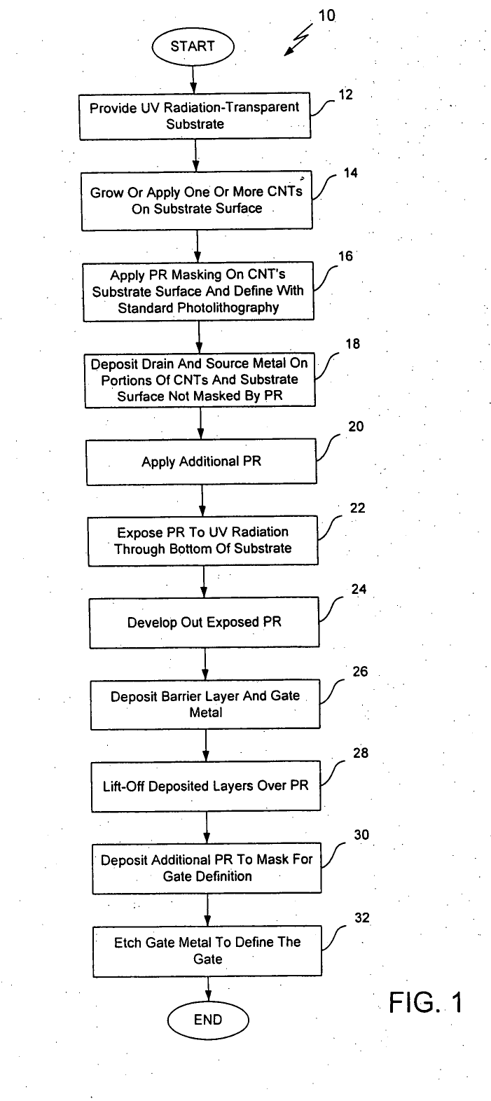

With reference now to FIGS. 1-3, embodiments of a method of fabricating self-aligned CNT FETs that overcome limitations in existing CNT FETs are described herein. Embodiments of the method provide a self-aligned process flow that minimizes layer-to-layer spacing in CNT FETs. Minimizing layer-to-layer spacing in CNT FETs overcomes the disadvantages described above regarding existing CNT FETs and existing CNT FET fabrication processes. Specifically, minimizing layer-to-layer spacing reduces parasitic capacitance that would charge up and discharge slowly if layer-to-layer spacing were too large. Such parasitic capacitance limits the ultimate speed at which a device may operate.

Layer-to-layer spacing may be reduced by overlapping the gate metal with the drain and the source in the CNT FET. However, this is problematic as the gate dielectric is typically thin and would likely not provide dielectric coverage as the gate metal crosses the drain or source edge. Another problem is the overlapping area of gate and drain (or gate and source) would create a relatively large and parasitic capacitance.

In embodiments of the method of fabricating self-aligned CNT FETs, a substrate material that is transparent to ultraviolet (UV) radiation is used. Such substrate material includes but is not limited to quartz. In such embodiments, using a UV transparent substrate allows a layer to be patterned on a front-side of the substrate with a material opaque to UV radiation (e.g., titanium or gold) and, after coating the front-side of the substrate with photoresist (PR) (photoresist is a light sensitive material, typically a liquid polymeric material, used in several industrial processes, such as photolithography and photoengraving to form a patterned coating on a surface), the PR is exposed with UV radiation through the back-side of the substrate. In this matter the pattern is exposed with the UV radiation through the UV radiation transparent substrate. The initial UV radiation opaque layer (e.g., gold layer) serves as a mask blocking the UV radiation exposure and the PR. Only the area of the PR without the opaque layer will be exposed and can be developed away. A variety of PRs, particularly useful as deep UV (DUV) photoresists, may be used, such as polyhydroxystyrene-based polymers with a photoacid generator providing a solubility change, benzene-chromophore and diazonaphthoquinone-novolac resin (DNQ-novalec) mixtures, etc.

With reference again to FIG. 1, shown is a flowchart illustrating an embodiment of method 10 of fabricating self-aligned CNT FETs. A UV radiation transparent substrate is provided, block 12. In an embodiment, the substrate is quartz. One or more CNTs are grown or applied on substrate surface, block 14. CNTs may be grown by chemical vapor deposition (CVD). CVD includes flowing a gas such as methane through a furnacetube at ˜900° C. Inside the furnacetube is a substrate with a catalyst such as iron (Fe) particles that allow the initial growth of the CNTs. CNTs can also be produced and put in solution, then spun onto a substrate (e.g., wafer) where the solution is evaporated off, leaving CNTs on the substrate surface.

A PR masking is applied on the CNTs on the substrate surface (the substrate front-side) and defined with standard photolithography, block 16. Standard photolithography generally includes four steps: PR coating, exposure, development, and hard-baking. In the PR coating, a substrate, is coated with PR. The PR is the material that an image will be transferred to during the photolithography process and is UV-sensitive. The coating process is typically performed by spinning the substrate at speeds between 1000 and 5000 rpm. PR is deposited onto the substrate surface during this dynamic movement to ensure even coating over the entire substrate surface. Other alternatives include using dry film PRs, which can be laminated into place to create the photo-patternable surface. Once the substrate has been coated with PR, the exposure includes exposing the substrate on an exposure tool. For example, UV radiation may be shined through a glass plate which is partially coated with chrome or other metal patterns on its surface. Alternatively, a soda lime plate may be used This plate, termed a photomask or mask, has the master image of the device on it. By shining UV radiation through the mask and onto the substrate, individual areas of the PR are selectively exposed to light to define the PR mask (i.e., the areas not masked or blocked by the metal patterns on the plate). This exposure causes a chemical change in the PR. Development includes immersing the exposed substrate in a developer solution. Developer solutions are chemical solutions that are usually aqueous and will dissolve the areas of the PR that were exposed to light, leaving the defined PR mask pattern defined by the photomask. After development, the substrate is baked in an oven or hot plate at temperatures generally between 100-120° C. to perform the hard-bake. This hard-bake drives off liquids that may have been absorbed on the substrate and crosslinks the remaining PR. Crosslinking the PR mask increases mechanical and chemical stability of the material, allowing it to be used in further substrate processing.

The PR masking masks a portion of the CNTs and the substrate surface. Using a material that is opaque to UV radiation, drain and source metal is deposited on the portions of the CNTs and substrate surface not masked by the PR, block 18. The initial PR may be lifted off. Exemplary drain and source metal include, without limitation, Titanium (Ti) and Gold (Au). Additional PR is applied, such as by being spun on (e.g., by spinning substrate as described above), block 20. The additional PR is applied on the portions of the CNT and substrate not covered by the UV-opaque material and on top of the UV-opaque material itself.

The PR is exposed to UV radiation through the bottom (i.e., back-side) of the substrate, block 22. The PR may be exposed to UV radiation by illuminating, flooding or bombarding the substrate bottom with UV radiation since the UV-opaque drain and source metal will only allow exposure of a portion of the PR not blocked by the UV-opaque material. The UV radiation passes through the UV-transparent substrate. The exposed PR is developed out (e.g., as described above in standard photolithography process), block 24. A barrier layer (e.g., Aluminum Oxide (Al₂O₃), Titanium Oxide (TiO₂), Silicon Oxide (SiO₂), etc.) and gate metal (e.g., Ti, Au, etc.) are deposited, block 26. The deposited layers are lifted-off over the PR, block 28. Lift-off is where the metal deposited on a making layer of PR is removed when the underlying PR is removed, typically in acetone. The metal deposited where there was not PR will remain. Additional PR is deposited to mask for gate definition, block 30. The gate metal may be etched to define the gate, block 32.

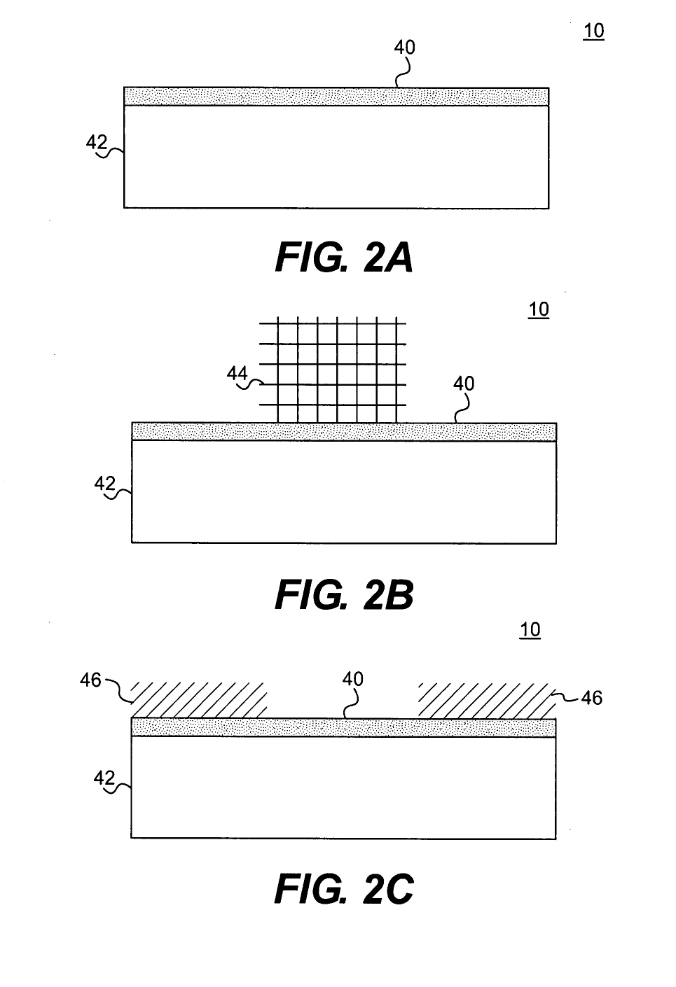

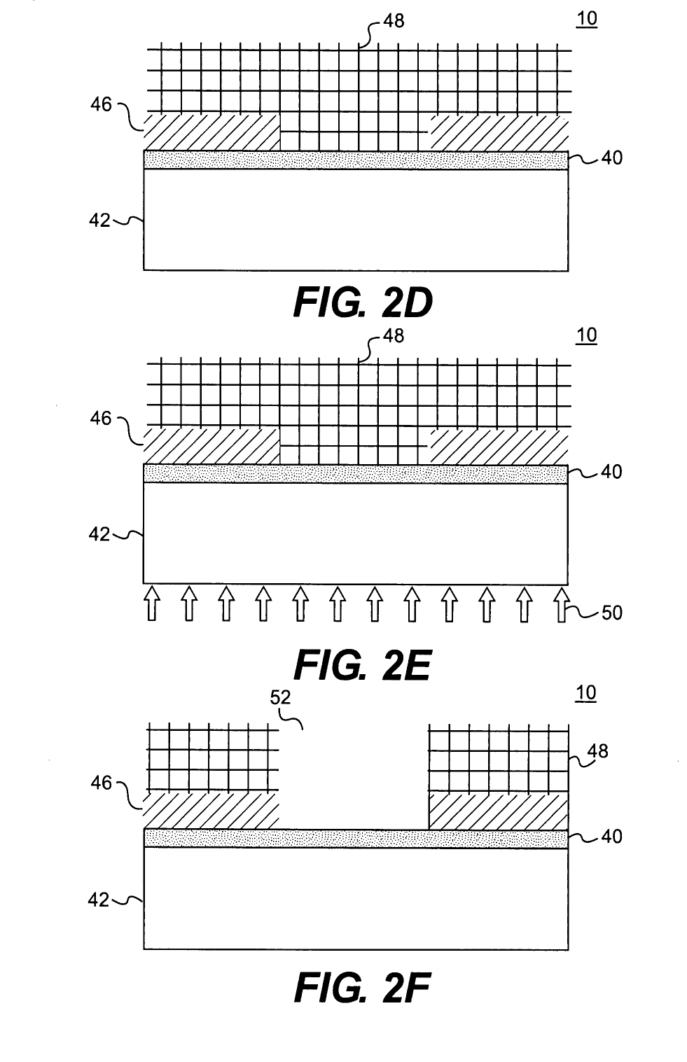

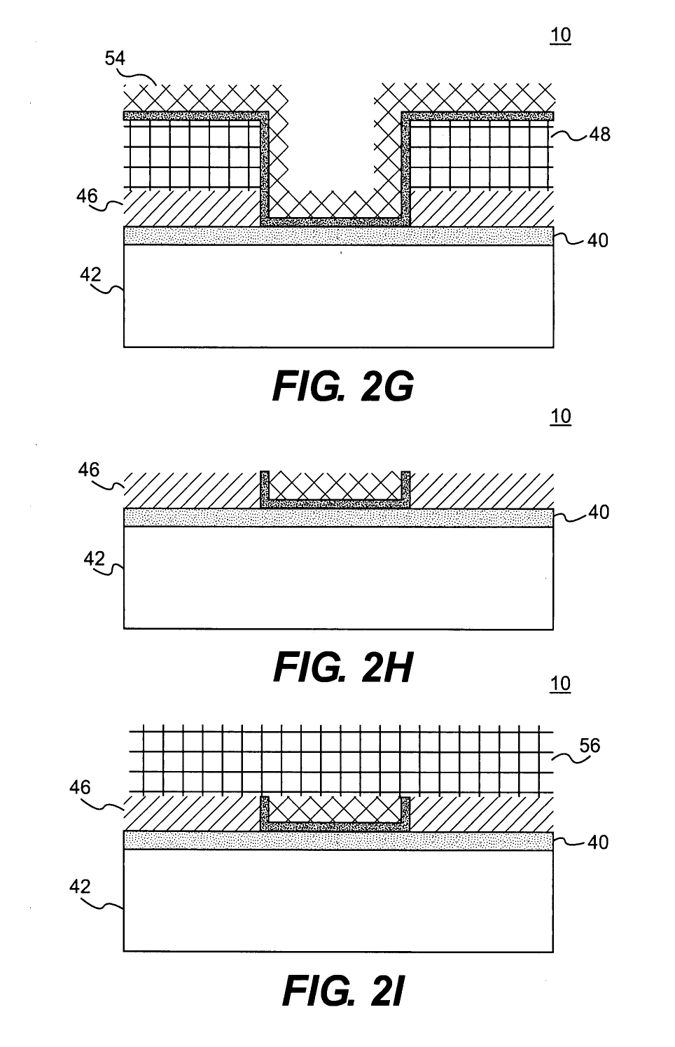

With reference now to FIGS. 2A-2I, shown are block diagrams illustrating method an embodiment of method 10 of fabricating self-aligned CNT FETs corresponding to FIG. 2. As shown in FIG. 2A, one or more CNTs 40 are grown or dispersed on quartz substrate 42. PR masking layer 44 is applied to CNT layer 40, as shown in FIG. 2B. UV opaque layer 46 is applied and PR masking layer 44 is removed or lifted-off, as shown in FIG. 2C. With reference now to FIG. 2D, additional PR layer 48 is spun-on or otherwise applied. Additional PR layer 48 is exposed to UV radiation 50 through substrate 42, as shown in FIG. 2E. With reference now to FIG. 2F, the exposed PR portion 52 of additional PR layer 48 is developed and removed. Bi-layer 54 (a barrier layer (e.g., Al₂O₃, TiO₂, SiO₂, etc.) and gate metal (e.g., Ti, Au, etc.)) is deposited, as shown in FIG. 2G. Deposited bi-layer 54 and additional PR layer 48 are lifted off, as shown in FIG. 2H. With reference now to FIG. 2I, PR strip 56 is dissolved, leaving the gate metal.

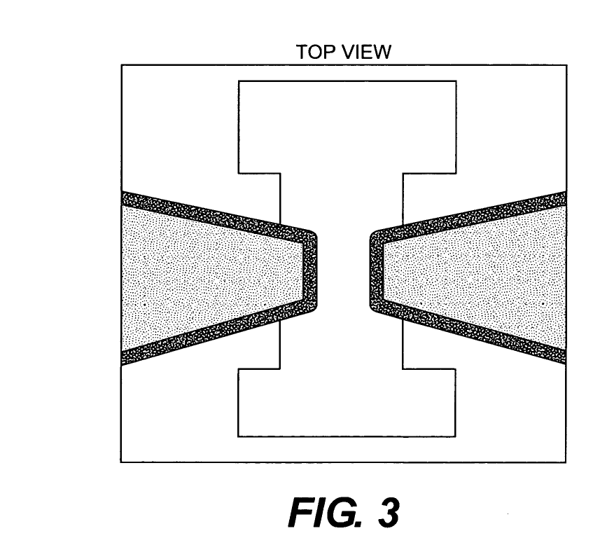

With reference now to FIG. 3, shown is a top view of a CNT FET fabricated according to method 10. The drain and source are connected by a CNT across the gap. Within the gap is a gate oxide on top of the CNT and a gate metal above that.

Selective Etching of Metallic CNTs

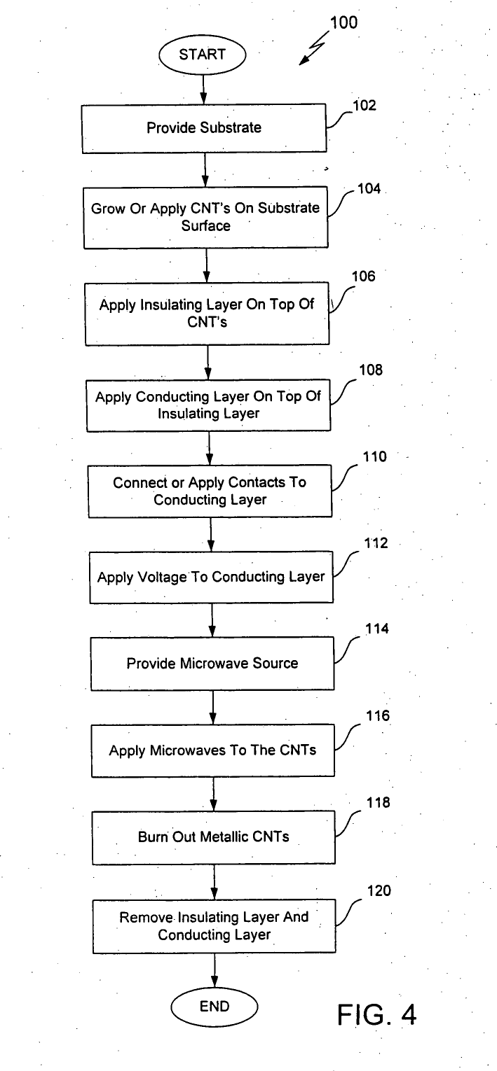

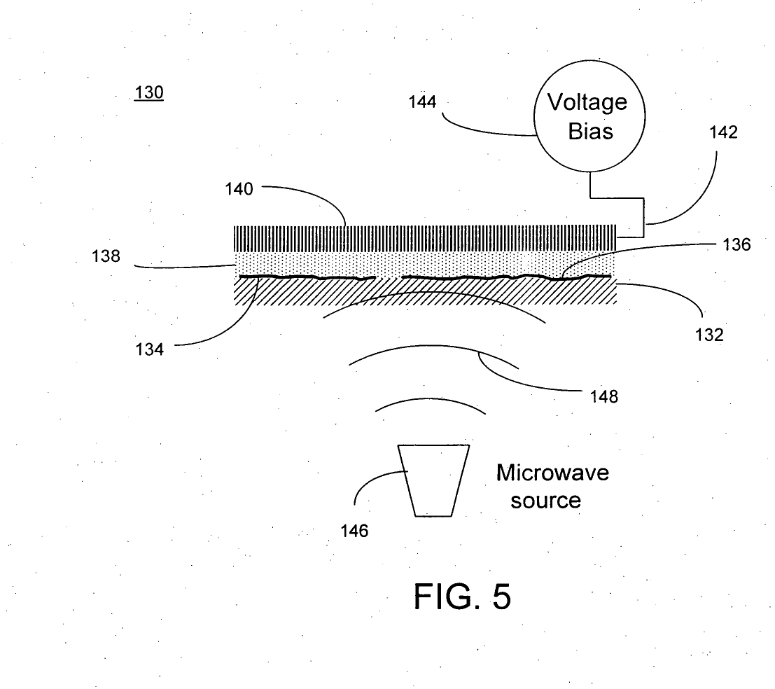

With reference now to FIGS. 4-5, embodiments of a method and apparatus for selectively etching metallic CNTs are described herein. The embodiments described herein allow for the selective elimination of metallic CNTs, overcoming the problems caused by the creation of metallic CNTs due to the variation of chirality during the CNT growing process.

Currently, the problem of metallic CNTs being created is skirted by growing CNTs as normal and then selecting and studying devices that only have useful, semi-conducting CNTs. However, this method is not easily adaptable for industrial manufacturing processes. In order to integrate CNT devices into a manufacturable process, a method is needed to eliminate metallic CNTs. Approaches have been proposed to engineer the size and shape of the catalyst, to multiply and re-grow a known semi-conducting CNT and to take advantage of a slight chemical selectivity as a function of chirality. These approaches have their own difficulties, unfortunately, and still may not entirely eliminate all metallic CNTs. The presence of any metallic CNTs has a direct and deleterious impact on device yield.

The method of selectively etching metallic CNTs described herein globally eliminates the undesirable metallic CNTs. The method may be used with any growth or spin-on technique and removes the eliminates metallic CNTs after the CNTs have been grown or spun-on. The embodiments shown take advantage of differing transport properties of CNTs to generate a current in the metallic CNTs. A relatively small current is enough to burn out a metallic CNT much like a filament in a light bulb that receives too much current. Temperatures in CNTs may be come as high as 1500 C with currents of only a few tenths of a microampere. In embodiments, the burning out affect may be enhanced by purposefully putting a source of oxygen in intimate contact with the CNT in the form of either a gas or an overlying oxide film.

With reference again to FIG. 4, shown is a flowchart illustrating method of selectively etching metallic CNTs 100. A substrate is provided, block 102. CNTs are grown or applied on a substrate surface, block 104. An insulating polymer or dielectric layer is applied on top of the CNTs, block 106. Insulating polymer is applied on top of the CNTs in order to electrically insulate the CNTs from the next deposition of metal (the later conducting layer). Otherwise, conducting layer will short the CNTs. The insulating polymer or dielectric may chosen from a variety of materials, including without limitation, Teflon® or photoresist (PR). The insulating layer may be spun-on. A conducting layer is applied on top of the insulating layer, block 108. The conducting layer may be spun-on or deposited (e.g., by spinning substrate at high speeds as described above). For example, the conducting layer may be a metallic film deposition or a spin-on of a conducting PR with metallic suspension. The conducting polymer may be used as the conducting layer. A poorly conducting layer is sufficient to voltage bias the CNTs while limiting the induced current created in the conducting layer from the microwave source (see below).

Contacts are connected or applied to the conducting layer, block 110. The contacts enable a voltage to be applied to the conducting layer. A voltage is applied to the conducting layer so that the conducting layer is biased to a sufficient voltage to deplete the conduction electrons only in the semi-conducting CNTs, block 112. For example, a voltage of 1-10V may be applied. Depleting the conduction or conducting electrons in the semi-conducting CNTs prevents the semi-conducting CNTs from conducting. A microwave source is provided, block 114, and microwaves are applied by the microwave source to the CNTs, block 116. The metallic CNTs will conduct and will “burn-out” in response to the microwave radiation, block 118. Since the semi-conducting CNTs are prevented from conducting, only the metallic CNTs will conduct, leaving the semi-conducting CNTs undamaged. The insulting layer and conducting layer are removed, block 120. After the removal of these layers, the CNTs may be continue to be processed and fabricated as a CNT FET, e.g., as described above with reference to FIGS. 2-4. If the insulating or conducting layers are PR, removing these layers may be accomplished simply by soaking the device in acetone.

With continuing reference to FIG. 4, in an alternative embodiment, the voltage applied to the conducting layer may be adjusted to reduce the conducting layer voltage bias. For example, the voltage applied in block 112 may be reduced to <1 volt. This would deplete the conduction electrons in only the most responsive of the semi-conducting CNTs. When the microwaves are applied, only the most responsive semi-conducting CNTs would be preserved; the remaining would be burnt-out. The depletion of conduction electrons in semi-conducting CNTs is temporary. I.e., when the voltage bias is removed, conduction electrons will return.

With reference now to FIG. 5, shown is a schematic diagram illustrating apparatus 130 for electively etching metallic CNTs (e.g., per method 100). As shown, apparatus 130 includes substrate 132, one or more CNTs, including metallic CNTs 134 and semi-conducting CNTs 136, insulating layer (e.g., spin-on dielectric) 138, conducting layer (e.g., spin-on conductor) 140, voltage contacts 142, voltage source 144 and microwave source 146. After insulating layer 138 and conducting layer 140 are applied, voltage source 134 provides a voltage bias to conducting layer 130, depleting conduction elections in semi-conducting CNTs 136. Microwave source 146 then applies microwaves 148, as shown, burning out metallic CNTs 134 (and less responsive semi-conducting CNTs 136 if voltage bias is reduced as described above).

CNT FET Gate-Oxide Fabrication Processes Using Anodization

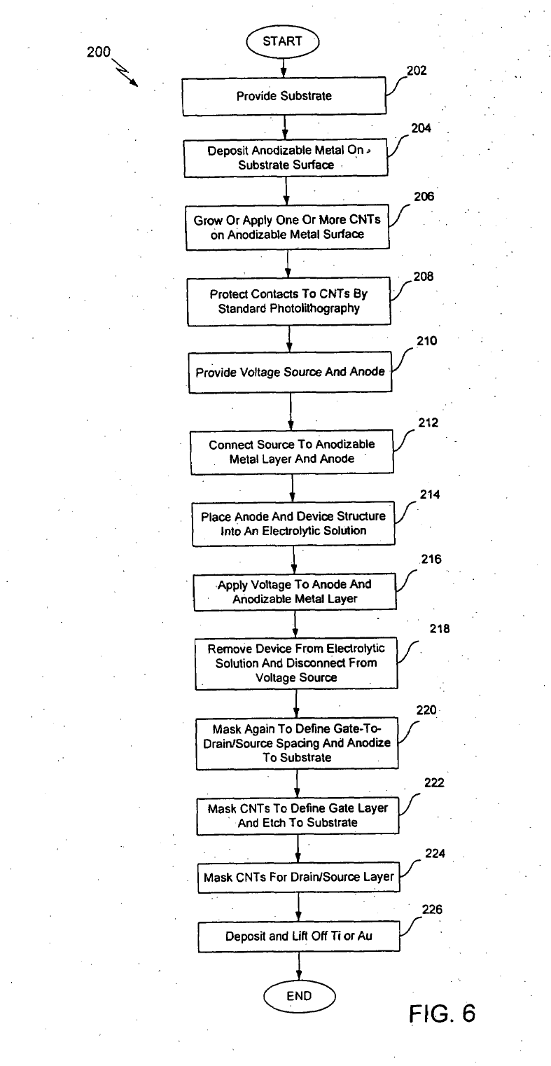

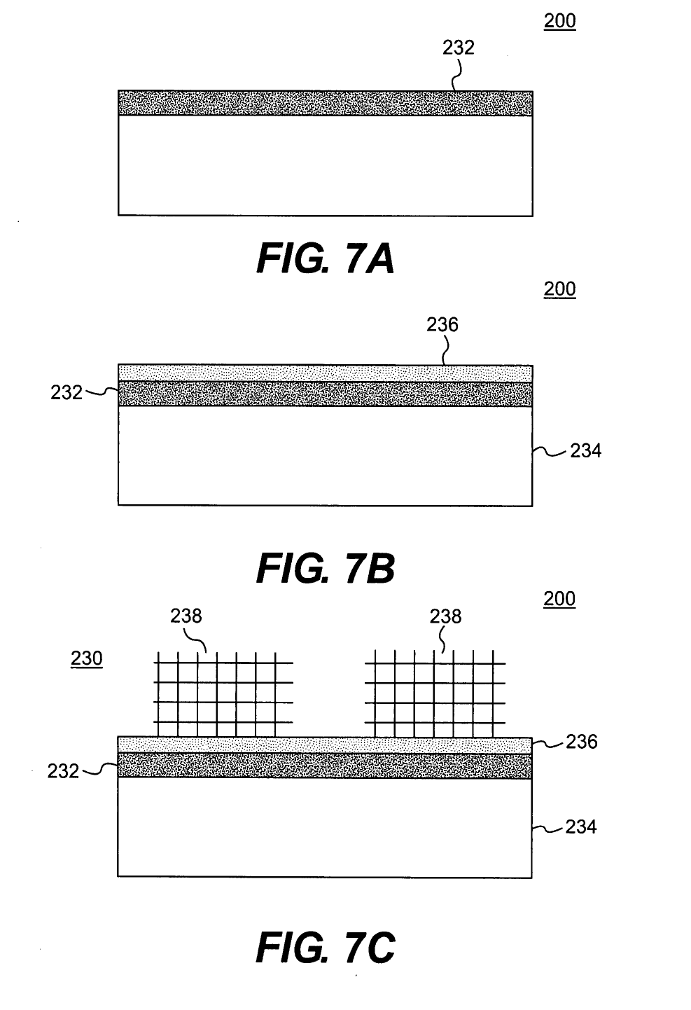

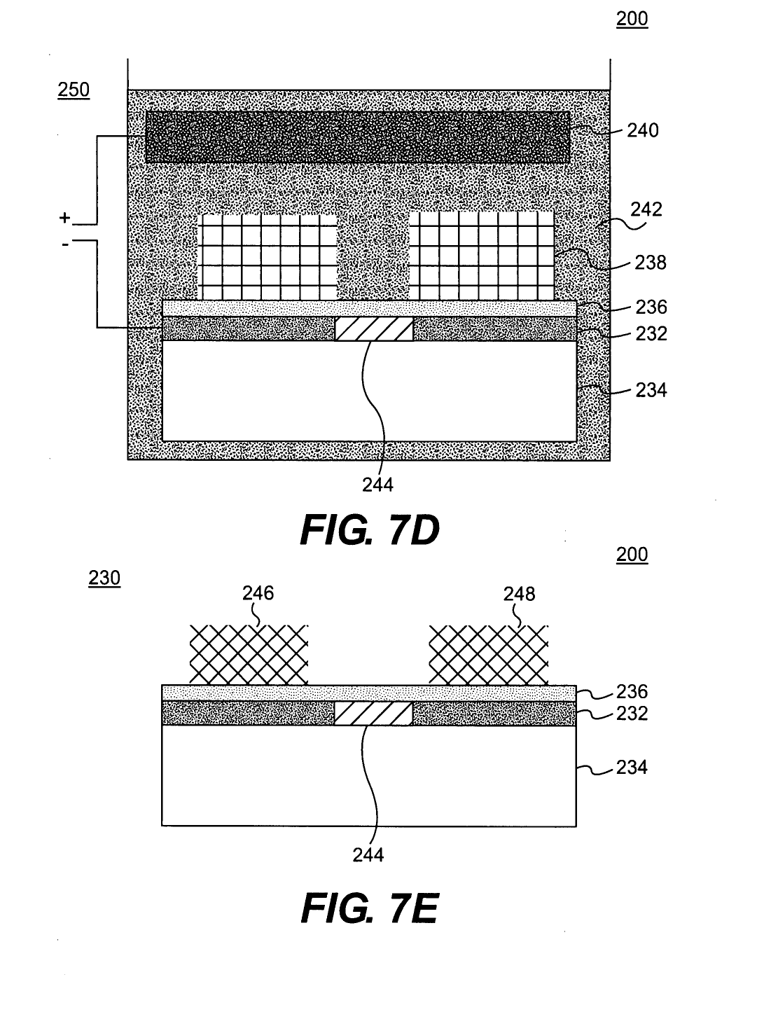

With reference now to FIGS. 6-7, embodiments of a method of fabricating an oxide in a CNT device are described. These embodiments overcome the problems described above that result from depositing an oxide on to CNTs or growing CNTs on an oxide material. In an embodiment, CNTs are grown or applied on a metallic surface. An oxide is subsequently grown beneath the CNT by anodization.

With reference to FIG. 6, shown is an embodiment of a method of fabricating an oxide in a CNT device 200. A substrate is provided, block 202. The substrate may be, e.g., quartz or other suitable material. An anodizable metal is deposited on the substrate surface, preferably as a film, block 204. The anodizable metal may be, e.g., Niobium (Nb) or other anodizable metal, such as Aluminum (Al) or Tantalum (Ta). One or more CNTs are grown or applied on the anodizable metal surface, block 206. One exemplary manner of growing the CNTs is to apply the CNT catalyst to the anodizable metal surface and place the structure (i.e., the substrate with anodizable metal and catalyst) into a furnace at an elevated temperature (e.g., ˜700 C) with flowing methane. Typically, the atmosphere in which the structure is located is reduced with a hydrogen/argon mix to react with any oxygen before putting into the furnace. The anodizable metal is unaffected by the reduced atmosphere. Likewise, an anodizable metal such as Nb, with a melting point of 2744 C, will be unaffected by the CNT growing temperature (e.g., 700 C). Alternatively, previously grown CNTs may be spun onto the anodizable metal surface.

Contacts to the CNTs may be protected, e.g., by standard photolithography, block 208 (the contacts are the metal that makes electrical contact to the CNTs, typically made of Au, Ti/Au or Pd). For example, PR may be applied to contacts on the CNT as a mask to protect the contacts. The defined PR covers the areas that you do not want to be in contact with the anodization solution. A voltage source and an anode are provided, block 210, and the source is connected to the anodizable metal layer and the anode, block 212. The anode and the entire device structure (i.e., substrate with anodizable metal and CNTs), or least a portion sufficient to submerge the anodizable metal layer and the adjacent portion of the substrate, is placed into an electrolytic solution, block 214. The electrolytic solution may be, for example, ammonium pentaborate or other electrolytic solutions. A voltage is then applied to the anode and the anodizable metal layer to anodize the anodizable metal layer underneath the CNTs, block 216. The voltage may be chosen to anodize a certain amount of anodizable metal. For example, if the anodizable metal layer is Nb, the Nb will anodize at the rate of 2.3 nm of niobium oxide per volt. The voltages applied to the anode and the anodizable metal layer will have opposing polarity (e.g., negative voltage to the anodizable metal layer and positive voltage to the anode). The anodization of the anodizable metal layer results in a sealed oxide with typically excellent dielectric integrity directly between the CNTs and any remaining unanodized metal. The unanodized metal layer may then serve as a gate metal in the final device. Since CNTs make poor electrical contact with the anodizable metal layer and have much higher resistivities, the CNT will not react and will not be anodized.

With continuing reference to FIG. 6, once the oxide layer is formed (e.g., in a Nb/NbOₓ/CNT layering), the rest of the CNT device (e.g., CNT FET) may be formed in a straightforward fashion at room temperature. The device is removed from the electrolytic solution and disconnected from the voltage source, block 218. If the end device will be a CNT FET, the CNTs may be masked again to define gate-to-drain/source spacing and anodized to the substrate, block 220. A PR may be used to mask the CNTs. The CNTs may be masked to define the rest of the gate layer and etched to the substrate, block 222. The PR mask may be defined as described above, e.g., using standard photolithography. The CNTs are masked for the drain/source layer, block 224. Typically, Ti or Au is deposited and lifted off to create the drain and source and complete a basic CNT FET device, block 226.

With reference now to FIGS. 7A-7E, shown are block diagrams illustrating exemplary steps of an embodiment of a method of fabricating an oxide in a CNT device 200. As shown in FIG. 7A, anodizable metal 232, in this instance Nb, is deposited on substrate 234. Substrate 234 is a quartz substrate, as shown. FIG. 7B illustrates that CNTs 236 are grown on anodizable metal 232. Alternatively, previously grown CNTs 236 may be spun on to anodizable metal 232. As shown in FIG. 7C, contacts (not shown) to the device 230 are protected by standard photolithography (e.g., using PR masks 238).

With reference now to FIG. 7D, shown is apparatus 250 for fabricating an oxide in a CNT device 230. Apparatus 250 includes anode 240, electrolytic solution 242, a voltage source (not shown) and device 230. Anode 240 and anodizable metal 232 are electrically contacted to voltage source (not shown) and placed into electrolytic solution 242. A voltage is then applied that will anodize anodizable metal 232 under CNTs 236. An oxide (e.g., NbOx) layer 244 will result, between CNTs 236 and any remaining unanodized metal 232. As shown in FIG. 7E, device 230 is disconnected from voltage source, removed from electrolytic solution 242 and masked, and Ti or Au is deposited and lifted off to create drain 246 and source 248.

The terms and descriptions used herein are set forth by way of illustration only and are not meant as limitations. Those skilled in the art will recognize that many variations are possible within the spirit and scope of the invention as defined in the following claims, and their equivalents, in which all terms are to be understood in their broadest possible sense unless otherwise indicated.

1. A method of fabricating self-aligned carbon nanotube field-effect transistors (FET), comprising:
providing a substrate that is fabricated from a ultraviolet (UV) radiation transparent material;
placing one or more carbon nanotubes (CNTs) on a front-side of the substrate;
depositing a UV radiation-opaque material on a portion of the CNTs as FET drain and source;
applying photoresist (PR) on a portion of the CNTs not covered by Uv radiation-opaque material and on top of the UV radiation-opaque material;
illuminating a bottom-side of the substrate with UV radiation, whereby the UV radiation passes through the substrate and exposes a portion of the PR to the UV radiation;
developing the UV radiation-exposed PR, whereby the developed PR is removed;
depositing a bi-layer;
defining a FET gate; and
applying a PR mask.

2. The method of claim 1 further comprising:
masking a portion of the one or more nanotubes with PR prior to depositing the UV radiation-opaque material; and
lifting-off the PR mask after depositing the UV radiation-opaque material.

3. The method of claim 1 wherein the providing provides a quartz substrate.

4. The method of claim 1 wherein the placing grows the one or more CNTs on the front-side of the substrate.

5. The method of claim 1 wherein the depositing the UV radiation-opaque material deposits Titanium (Ti) as the drain and source.

6. The method of claim 1 wherein the depositing the UV radiation-opaque material deposits Gold (Au) as the drain and source.

7. The method of claim 1 wherein the depositing a bi-layer deposits a barrier layer and gate metal.

8. The method of claim 7 wherein the barrier layer is chosen from a list consisting of: Aluminum Oxide (Al₂O₃), Titanium Oxide (TiO₂) and Silicon Oxide (SiO₂).

9. The method of claim 7 wherein the gate metal is chosen from a list consisting of: Ti and Au.

10. The method of claim 1 wherein the defining the gate metal comprises etching the gate metal

11. The method of claim 1 further comprising lifting-off the deposited bi-layer.

12. A CNT FET manufactured according to the method of claim 1.

13. The method of claim 1 in which the placing one or more CNTs on the substrate surface places a plurality of CNTs on the substrate surface including semi-conducting CNTs and metallic CNTs, the method further comprising:
depleting conduction electrons in the semi-conducting CNTs, whereby at least some of the semi-conducting CNTs are prevented from conducting; and
burning out the metallic CNTs.

14. A method of selectively etching metallic carbon nanotubes (CNTs), comprising:
providing a substrate;
placing a plurality of CNTs on a surface of the substrate, in which the CNTs include semi-conducting CNTs and metallic CNTs;
depleting conduction electrons in the semi-conducting CNTs, whereby at least some of the semi-conducting CNTs are prevented from conducting; and
burning out the metallic CNTs.

15. The method of claim 14 in which depleting conduction electrons comprises:
applying an insulating layer on the CNTs;
applying a conducting layer on the insulating layer; and
applying a voltage to the conducting layer so that the conducting layer is biased to a sufficient voltage to deplete conduction electrons in the semi-conducting CNTs are depleted.

16. The method of claim 15 in which the applying a voltage biases the conducting layer to a sufficient voltage to prevent all of the semi-conducting CNTs from conducting.

17. The method of claim 15 in which the applying a voltage biases the conducting layer to a sufficient voltage to prevent only the most responsive semi-conducting CNTs from conducting.

18. The method of claim 15 in which the applying an insulating layer applies an insulating polymer.

19. The method of claim 18 in which the insulating polymer is Teflon or photoresist.

20. The method of claim 15 in which the applying a conducting layer deposits a metallic film.

21. The method of claim 15 in which the applying a conducting layer spins-on a conducting photoresist.

22. The method of claim 15 further comprising:
connecting an electrical contact to the conducting layer;
providing a voltage source connected to the electrical contact, whereby the voltage source applies the voltage to the conducting layer.

23. The method of claim 14 in which the burning out the metallic CNTs further includes burning out some of the semi-conducting CNTs.

24. The method of claim 14 in which the burning out the metallic CNTs comprises:
providing a microwave source;
applying microwave radiation to the CNTs, whereby microwave radiation causes the metallic CNTs to conduct current until burning out.

25. The method of claim 14 further comprising removing the insulating layer and the conducting layer.

26. The method of claim 25 in which removing the insulating layer and the conducting layer comprises soaking the insulating layer and the conducting layer in acetone.

27. An electrical device comprising CNTs selectively etched according to claim 14.

28. The method of claim 14 in which the substrate is ultraviolet (UV) radiation transparent, the method further comprising:
depositing a UV radiation-opaque material on a portion of the CNTs as FET drain and source;
applying photoresist (PR) on a portion of the CNTs not covered by UV radiation-opaque material and on top of the UV radiation-opaque material;
illuminating a bottom-side of the substrate with UV radiation, whereby the UV radiation passes through the substrate and exposes a portion of the PR to the UV radiation;
developing the UV radiation-exposed PR, whereby the developed PR is removed;
depositing a bi-layer;
defining a FET gate; and
applying a PR mask.

29. The method of claim 14 in which placing the CNTs on the substrate surface comprises growing the CNTs on the substrate surface.

30. An apparatus for selectively etching metallic carbon nanotubes (CNTs), comprising:
a substrate;
a plurality of CNTs including metallic CNTs and semi-conducting CNTs;
an insulating layer;
a conducting layer;
a voltage source, in which the voltage source bias the conducting layer so as to deplete the semi-conducting CNTs of conduction electrons; and
a microwave source, in which the microwave source applies microwave radiation to the CNTs, causing the metallic CNTs to conduct current until burning out.

31. The apparatus of claim 30 further comprising an electrical contact connecting the voltage source to the conducting layer.

32. A method of fabricating an oxide in a carbon nanotube (CNT) device, comprising:
providing a substrate;
depositing an anodizable metal layer on a surface of the substrate placing one or more CNTs on the anodizable metal layer; and
anodizing the anodizable metal layer beneath the one or more CNTs, whereby an oxide layer is created beneath the one or more CNTs.

33. The method of claim 32 in which the anodizing comprises:
providing an anode;
placing the anodizable metal layer and the anode into an electrolytic solution; and
applying a voltage to the anode and the anodizable metal layer.

34. The method of claim 33 in which the electrolytic solution is ammonium 35.

35. The method of claim 32 further comprising providing a voltage source connected to the anodizable metal layer.

36. The method of claim 32 in which the anodizable metal layer is niobium.

37. The method of claim 32 in which the oxide layer is niobium oxide.

38. The method of claim 32 in which placing the one or more CNTs on the substrate surface comprises growing the one or more CNTs on the anodizable metal layer.

39. The method of claim 32 in which only a portion of the anodizable metal layer is anodized, leaving an unanodized metal layer.

40. The method of claim 32 further comprising defining a gate layer.

41. The method of claim 32 further comprising defining a drain and source layer.

42. The method of claim 41 in which the defining a drain and source layer comprises depositing and lifting off titanium or gold.

43. The method of claim 32 in which the providing a substrate provides a quartz substrate.

44. A CNT device fabricated according to the method of claim 32.

45. The method of claim 32 in which the placing places a plurality of CNTs on the anodizable metal layer, in which the CNTs include semi-conducting CNTs and metallic CNTS, the method further comprising:
depleting conduction electrons in the semi-conducting CNTs, whereby at least some of the semi-conducting CNTs are prevented from conducting; and
burning out the metallic CNTs.

46. The method of claim 45 in which depleting conduction electrons comprises:
applying an insulating layer on the CNTs;
applying a conducting layer on the insulating layer; and
applying a voltage to the conducting layer so that the conducting layer is biased to a sufficient voltage to deplete conduction electrons in the semi-conducting CNTs are depleted.

47. The method of claim 45 in which the substrate is ultraviolet (UV) radiation transparent, the method further comprising:
depositing a UV radiation-opaque material on a portion of the CNTs as FET drain and source;
applying photoresist (PR) on a portion of the CNTs not covered by UV radiation-opaque material and on top of the UV radiation-opaque material;
illuminating a bottom-side of the substrate with UV radiation, whereby the UV radiation passes through the substrate and exposes a portion of the PR to the UV radiation;
developing the UV radiation-exposed PR, whereby the developed PR is removed;
depositing a bi-layer;
defining a FET gate; and
applying a PR mask.

48. An apparatus for fabricating an oxide in a carbon nanotube (CNT) device, comprising:
a substrate;
an anodizable metal layer on a surface of the substrate;
one or more CNTs placed on the anodizable metal layer;
an anode;
a electrolytic solution submerging the anode and the anodizable metal layer; and
a voltage source connected to the anode and the anodizable metal layer, in which the voltage source applies a voltage to the anode and the anodizable metal layer, anodizing the anodizable metal layer to produce an oxide beneath the one or more CNTs.
